(19) United States
(12) Patent Application Publication
(10) Pub. No.: US 2003/0170978 A1
(43) Pub. Date: Sep. 11, 2003

(54) Method of fabricating a dual damascene structure on a semiconductor substrate

(76) Inventor: Shyh-Dar Lee, Hsinchu Hsien (TW)

Correspondence Address: BIRCH STEWART KOLASCH & BIRCH, PO BOX 747, FALLS CHURCH, VA, 22040-0747, US

(21) Appl. No.: 10/087,776

(22) Filed: Mar. 5, 2002

(51) Int. Cl. H01L 21/4763; H01L 21/31; H01L 21/461; H01L 21/302

(52) U.S. Cl. 438/638; 438/687; 438/725; 438/780

(57) ABSTRACT

A method of fabricating a dual damascene structure on a semiconductor substrate having a conductive structure. First, a deposited dielectric layer, a spin-coated dielectric layer, and a hard mask with a via opening are sequentially formed on the semiconductor substrate. Then, a photoresist pattern having a trench opening is formed on the hard mask. The spin-coated dielectric layer is etched through the via opening while the hard mask is used as the etching mask. Next, the hard mask is etched using the photoresist pattern as the etching mask to create a damascene opening including the via opening and the trench opening. The spin-coated dielectric layer and the deposited dielectric layer are then etched through the damascene opening to form a dual damascene structure to expose the conductive structure.

### BACKGROUND OF THE INVENTION

1. Field of the Invention

The present invention relates to the manufacture of semiconductor devices, more particularly, to a method of fabricating a dual damascene structure on a semiconductor substrate.

2. Description of the Related Art

Semiconductor manufacturers must continually improve the power and performance of semiconductor devices while keeping device size to a minimum. In an effort to maintain a small device size, most semiconductor manufacturers reduce individual components of the device to minimal dimensions. Furthermore, manufacturers are using methods such as vertical integration of the components to reduce the device area consumed by the components. But by packing the components in a higher and higher density, the need for higher performance interconnects arises. As the cross sectional area of the interconnects shrinks, line resistance and current density capacity become limiting factors of total chip performance. For example, aluminum, which has commonly been used for interconnects, has problems associated with electromigration and lowered heat dissipation. Copper, which has a lower resistivity and a greater electromigration lifetime, eliminates many of the existing problems associated with using aluminum. However, there are difficulties with fabricating copper interconnects using conventional etching techniques since copper material does not lend itself well to conventional plasma etching.

A recent approach to solving the problem of interconnecting the various conductive layers involves etch and mask sequences generally known in the art as damascene techniques. The damascene technique involves forming a plurality of trenches in a layer of insulator and subsequently filling them with metal, by way of example, copper, which is then polished down to the surface of the insulator to form the desired metal pattern. In a process generally known as dual damascening, both the metal trenches described above and the via interconnects electrically connecting the aforementioned metal pattern and various other conductive layers are typically filled simultaneously.

By way of example, FIGS. 1A to 1G are cross-sections showing the manufacturing steps of a dual damascene structure known in the prior art. FIG. 1A shows a semiconductor substrate 100, having copper lines 103 in a dielectric layer 102. A sealing layer 104 is deposited over the semiconductor substrate 100. Next, a dielectric layer 106 is formed on the sealing layer 104 by chemical vapor deposition or spin coating. An antireflection coating (ARC) layer 110 is formed on the dielectric layer 106.

As shown in FIG. 1B, a photoresist pattern 112 having via openings is formed on the ARC layer 110 by conventional photolithography. The dielectric layer 106 is then etched until vias 114 aligning to the metal structures 103 are created. Then, the photoresist pattern 112 is stripped to expose the upper surface of the ARC layer 110 as shown in FIG. 1C.

Next, referring to FIG. 1D, an organic material serving as the sacrificial material 116 fills a part of vias 114 by spin coating. A photoresist pattern 118 with a trench opening 120 is formed on ARC layer 110 by conventional photolithography, as shown in FIG. 1E. Afterward, as shown in FIG. 1F, the dielectric layer 106 is etched using the photoresist pattern 118 and the sacrificial material 116 as the etching mask to form a deep via 127 and a dual damascene structure DS consisting of a via 124 and a trench 122. In this step, the sealing layer 104 serves as the etching stop layer. Next, the sealing layer 104 is partially removed through the dual damascene structure DS to expose the metal structure 103.

Finally, referring to FIG. 1G, a deep copper plug 128 and a dual damascene copper 126 are formed by electroplating a copper layer into the dual damascene structure DS and the deep via 127 followed by chemical mechanical polishing the copper layer to planarize the surface.

One of the problems of the standard dual damascene process is associated with maintaining a proper vertical profile of the vias etched in the dielectric layer. Possible undesirable effects include bowing or sloping sidewalls, residue on the bottom surface of the via or on the metal layer. Serious challenges may also arise with photoresist removal, which changes the etching chemistry, which in turn may impact the vertical profile of the vias if the dielectric material is spin on polymer (SOP). Another problem is formation of an organic sacrificial material 116 in the via 114. This can cause high manufacturing costs, especially in scaled down devices.

Therefore, improved methods are called for that allow the formation of a copper dual damascene structure that will solve the aforementioned problems.

### SUMMARY OF THE INVENTION

In view of the above disadvantages, an object of the invention is to provide a method of fabricating a dual damascene structure on a semiconductor substrate using both the deposited dielectric layer and the spin-coated dielectric layer so as to maintain a proper profile of the dual damascene structure.

It is another object of the invention to provide a method of fabricating a dual damascene structure on a semiconductor substrate. This method does not use the sacrificial material, thereby reducing manufacturing costs.

Accordingly, the above objects are attained to provide a method of fabricating a dual damascene structure on a semiconductor substrate having a conductive structure. First, a deposited dielectric layer with a thickness of 2000 angstroms to 6000 angstroms, a spin-coated dielectric layer with a thickness of 2000 angstroms to 6000 angstroms, and a hard mask with a via opening are sequentially formed on the semiconductor substrate. Then, a photoresist pattern having a trench opening is formed on the hard mask. The spin-coated dielectric layer is etched through the via opening while the hard mask is used as the etching mask. Next, the hard mask is etched using the photoresist pattern as the etching mask to create a damascene opening including the via opening and the trench opening. The spin-coated dielectric layer and the deposited dielectric layer are then etched through the damascene opening to form a dual damascene structure to expose the conductive structure.

In an embodiment of the invention, the formation of the hard mask mentioned above with a via opening further comprises the steps of depositing a silicon nitride layer on the spin-coated dielectric layer; forming a photoresist pattern with a via opening on the silicon nitride layer; etching the silicon nitride layer through the via opening to create a hard mask; and removing the photoresist pattern.

In another embodiment of the invention, the spin-coated dielectric layer can be an organic low-k material layer (i.e. spin on polymer) such as SilK manufactured by Dow Chemical Corp, fluorinated poly (arylene ether) (FLARE) manufactured by Applied Signal Corporation, poly (arylene ether), or fluorine-doped silicon glass. On the other hand, the deposited dielectric layer is preferably an inorganic silicon-based layer formed by chemical vapor deposition (CVD). For example carbon-doped silicon, black diamond, or Coral manufactured by Applied Materials Corporation.

Yet another embodiment of the invention further comprises formation of a copper layer to fill the dual damascene structure followed by chemical mechanical polishing of the copper layer.

The above objects are also attained to provide a method of fabricating a dual damascene structure on a semiconductor substrate having a conductive structure. First, a first dielectric layer, a second dielectric layer, and a hard mask with a via opening are sequentially formed on the semiconductor. Second, a photoresist pattern having a trench opening is formed on the hard mask, wherein the photoresist pattern has the same etching characteristic as the second dielectric layer. Third, the second dielectric layer is etched through the via opening while the hard mask is used as the etching mask. Fourth, the hard mask is etched using the photoresist pattern as the etching mask to create a damascene opening including the via opening and the trench opening. Fifth, the second dielectric layer and the first dielectric layer are etched through the damascene opening to form a dual damascene structure. Finally, a copper layer is electroplated to fill the dual damascene structure to form a copper interconnect.

According to the invention, a new process of dual damascene structure is provided to eliminate the step of forming the organic sacrificial material thereby reducing manufacturing costs. Furthermore, this method can maintain a proper profile of the dual damascene structure.

### BRIEF DESCRIPTION OF THE DRAWINGS

FIGS. 1A to 1G are cross-sections showing the manufacturing steps of a dual damascene structure, in accordance with the prior art.

FIGS. 2A to 2H are cross-sections showing the manufacturing steps of a dual damascene structure, in accordance with the present invention.

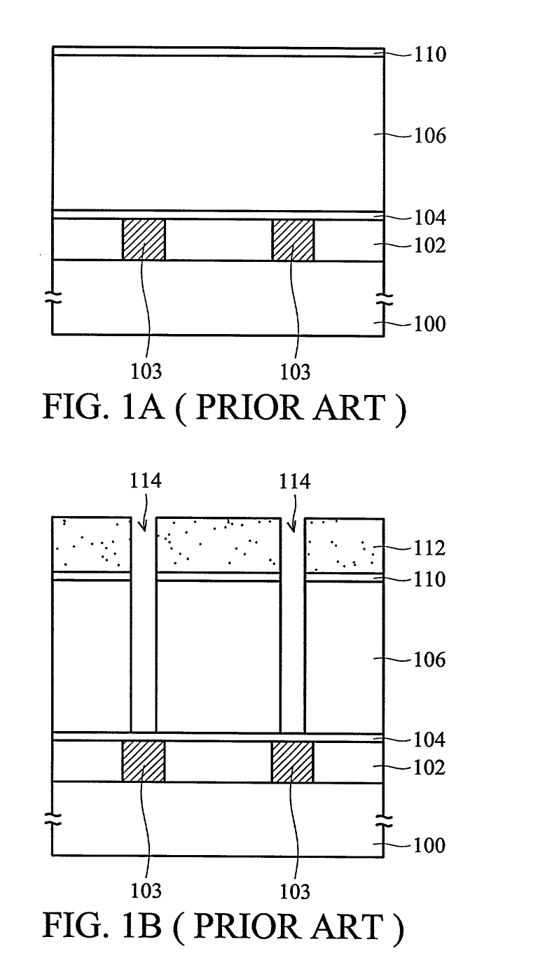

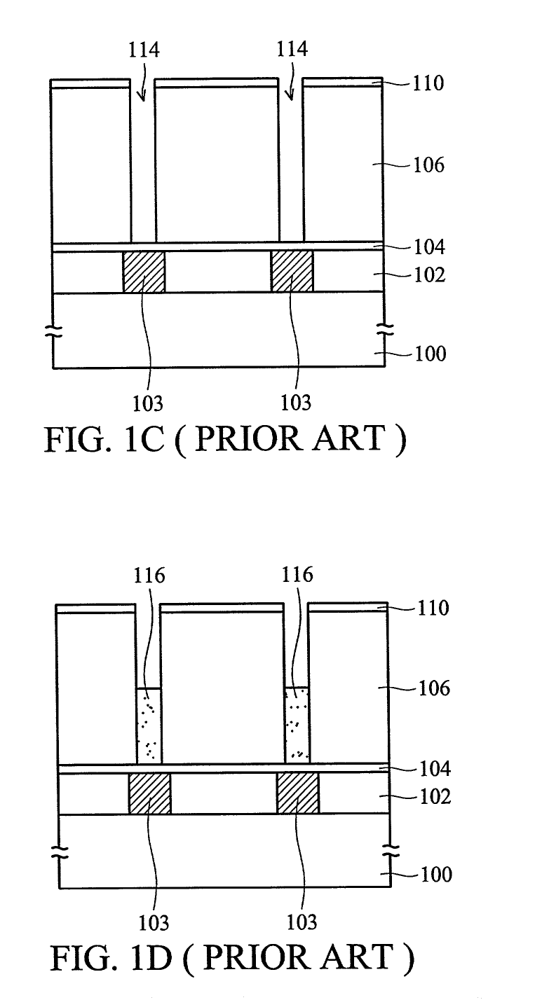

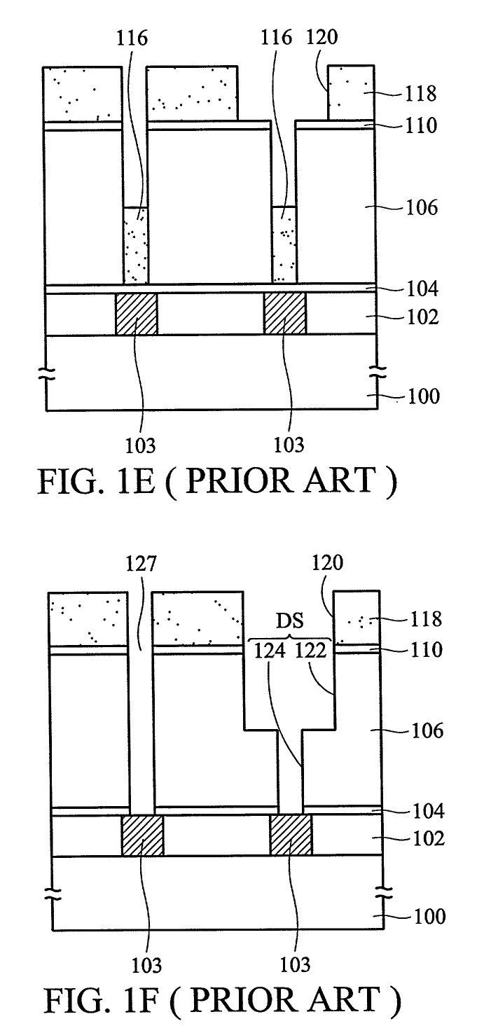

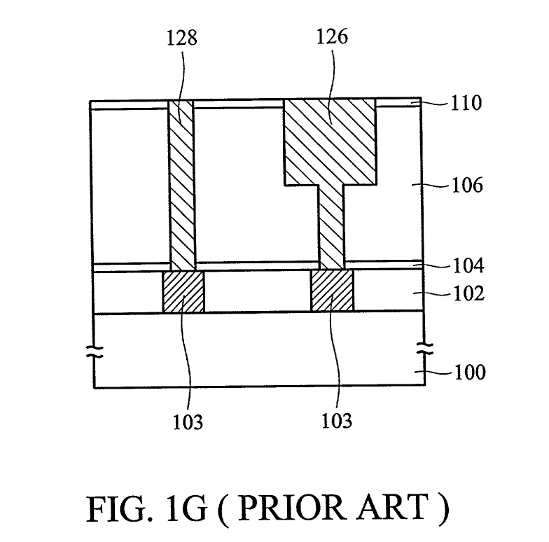

### DETAILED DESCRIPTION OF THE PREFERRED EMBODIMENTS

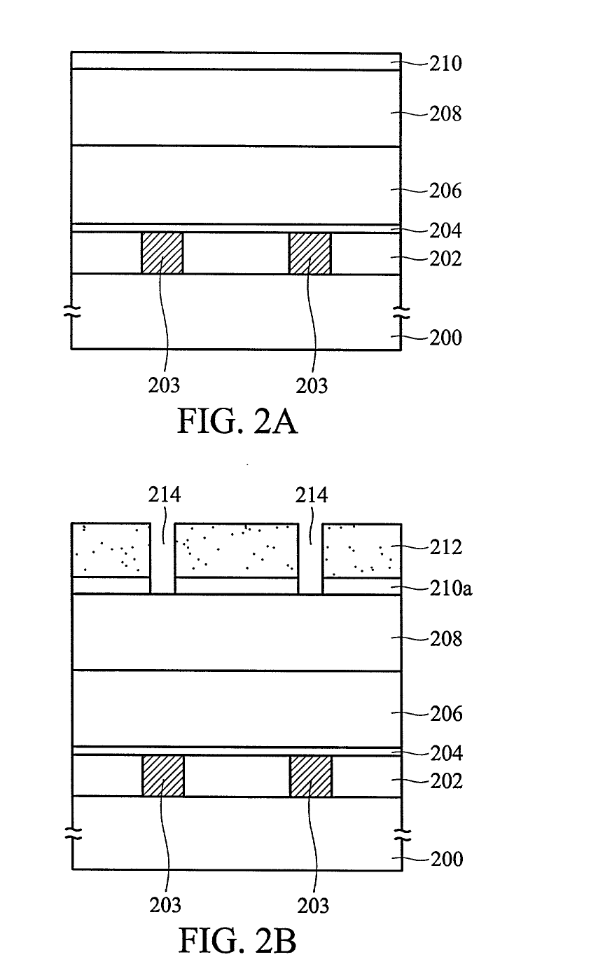

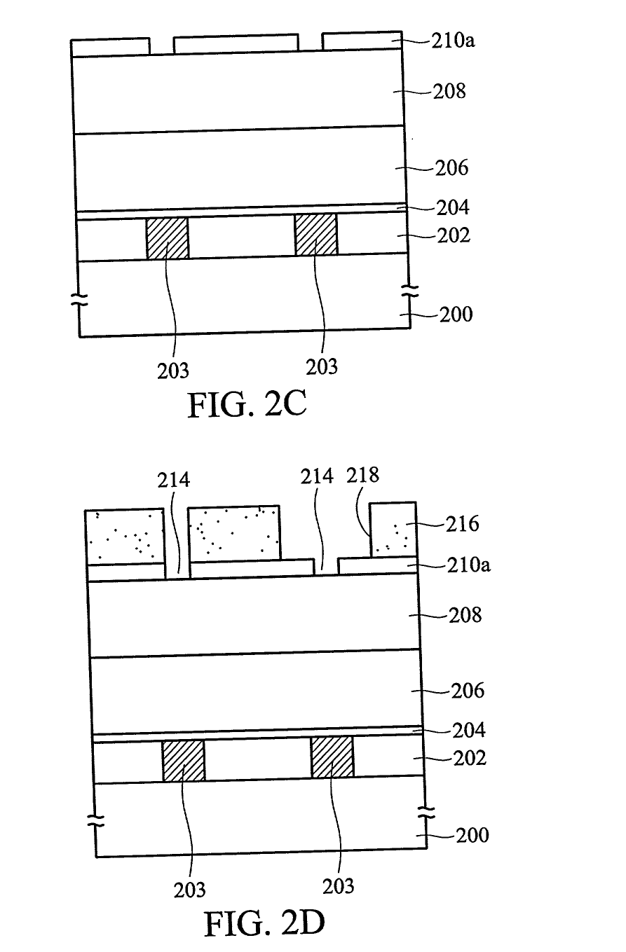

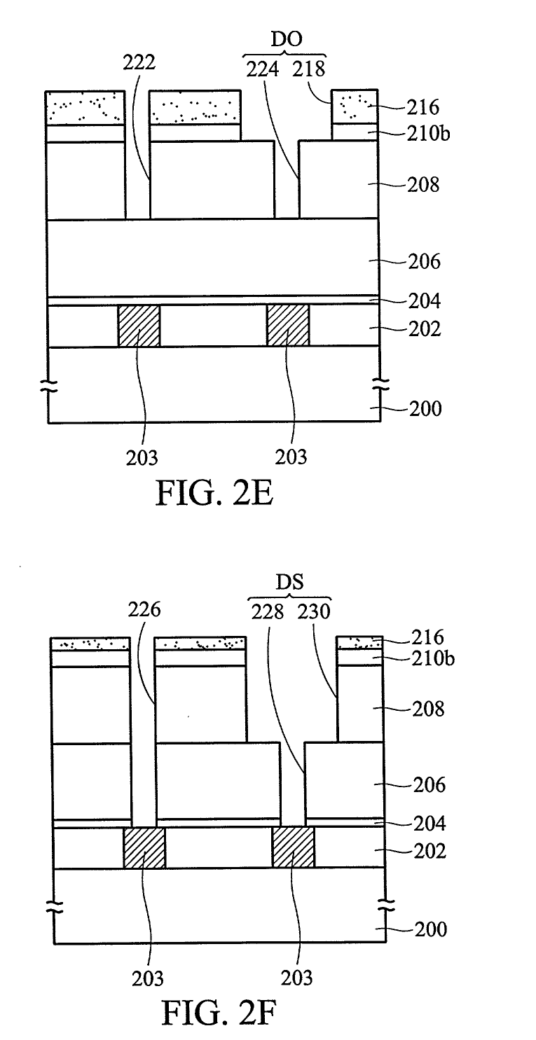

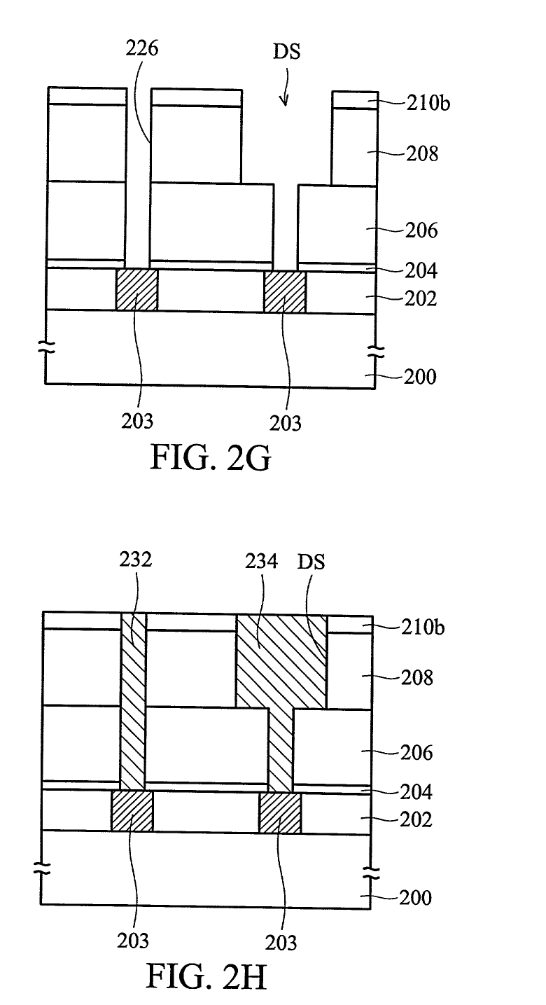

FIGS. 2A to 2H are cross-sections showing the manufacturing steps of a dual damascene structure, in accordance with the present invention.

FIG. 2A shows a semiconductor substrate 200, having conductive structures 203 such as copper lines formed in a dielectric layer 202. A sealing layer 204 consisting of silicon nitride is deposited over the semiconductor substrate 200. The sealing layer 204 also serves as the etching stop layer in the subsequent process. Next, a deposited dielectric layer 206 with a thickness of 2000 angstroms to 6000 angstroms and a spin-coated dielectric layer 208 with a thickness of 2000 angstroms to 6000 angstroms are sequentially formed on the sealing layer 204. The deposited dielectric layer 206 is preferably an inorganic silicon-based layer of carbon-doped silicon, black diamond, or Coral manufactured by Applied Materials Corporation formed by chemical vapor deposition. The spin-coated dielectric layer 208 is preferably a low k organic material, also called “spin on polymer (SOP)”. This SOP is SilK manufactured by Dow Chemical Corp, fluorinated poly (arylene ether) (FLARE) manufactured by Applied Signal Corporation, poly (arylene ether), or fluorine-doped silicon glass formed by spin coating.

A silicon nitride layer 210 or a silicon oxy-nitride layer is then formed on the spin-coated dielectric layer 208 followed by the formation of an anti-reflection coating layer (not shown) consisting of titanium/titanium nitride or silicon oxynitride.

As shown in FIG. 2B, a photoresist pattern 212 having via openings 214 is formed on the silicon nitride layer 210 with the anti-reflection coating layer formed thereon by conventional photolithography comprising photoresist coating, photoresist exposing, and developing. The silicon nitride layer 210 is etched by reactive ion etching (RIE) through the openings 214 to leave a hard mask 210a composed of an underlying silicon nitride layer and titanium/titanium nitride. The via pattern aligned to at least one of the conductive structure 203 is therefore transferred to the hard mask 210a in this step. As shown in FIG. 2C, the photoresist pattern 212 is then stripped to expose the upper surface of the hard mask 210a.

Next, referring to FIG. 2D, a photoresist pattern 216 with a trench opening 218 is formed on the hard mask 210a by conventional photolithography. As shown in FIG. 2E, the spin-coated dielectric layer 208 is etched through the via opening 214 while the hard mask 210a is used as the etching mask until the deposited dielectric layer 206 is exposed so as to form intermediate vias 222 and 224. In this step, the photoresist pattern 216 is partially removed. This is because the photoresist pattern 216 material and the spin-coated dielectric layer 208 material tend to have similar chemical characteristics (a similar etching rate).

Afterward, the photoresist pattern 216 is used as the etching mask to transfer the trench pattern to the hard mask 210a so that the hard mask 210a is etched through the trench opening 218 mentioned above to leave a new hard mask 210b and create a damascene opening DO. The damascene opening DO includes the trench opening 218 and the intermediate via 224.

Referring now to FIG. 2F, the spin-coated dielectric layer 208 and the deposited dielectric layer 206 are etched through the damascene opening DO while the residual photoresist pattern 216 and the hard mask 210b are used as the etching mask so that a deep via 226 and a dual damascene structure DS including the via 228 and the trench 230 are created. The sealing layer 204 is then removed to expose the conductive structure 203 as shown in FIG. 2G.

Finally, referring to FIG. 2H, a deep copper plug 232 and a dual damascene copper 234 are formed by electroplating a copper layer into the dual damascene structure DS and the deep via 226 followed by chemical mechanical polishing (CMP) the copper layer to planarize the surface.

While the invention has been described with reference to various illustrative embodiments, the description is not intended to be construed in a limiting sense. Various modifications of the illustrative embodiments, as well as other embodiments of the invention, will be apparent to those person skilled in the art upon reference to this description. It is therefore contemplated that the appended claims will cover any such modifications or embodiments as may fall within the scope of the invention defined by the following claims and their equivalents.

What is claimed is:

1. A method of fabricating a dual damascene structure on a semiconductor substrate having a conductive structure, comprising the steps of:
sequentially forming a deposited dielectric layer, a spin-coated dielectric layer, and a hard mask with a via opening on the semiconductor substrate;
forming a photoresist pattern having a trench opening on the hard mask;
etching the spin-coated dielectric layer through the via opening while the hard mask is used as the etching mask;
etching the hard mask using the photoresist pattern as the etching mask to create a damascene opening including the via opening and the trench opening; and
etching the spin-coated dielectric layer and the deposited dielectric layer through the damascene opening to form a dual damascene structure to expose the conductive structure.

2. The method of fabricating a dual damascene structure on a semiconductor substrate as claimed in claim 1, wherein the formation of the hard mask with a via opening further comprises the step of:
depositing a silicon nitride layer on the spin-coated dielectric layer;
forming a photoresist pattern with a via opening on the silicon nitride layer;
etching the silicon nitride layer through the via opening to create a hard mask; and
removing the photoresist pattern.

3. The method of fabricating a dual damascene structure on a semiconductor substrate as claimed in claim 1, wherein the spin-coated dielectric layer is an organic low-k material layer.

4. The method of fabricating a dual damascene structure on a semiconductor substrate as claimed in claim 3, wherein the organic low-k material layer is SilK manufactured by Dow Chemical Corp, fluorinated poly (arylene ether) (FLARE) manufactured by Applied Signal Corporation, poly (arylene ether), or fluorine-doped silicon glass.

5. The method of fabricating a dual damascene structure on a semiconductor substrate as claimed in claim 1, wherein the deposited dielectric layer is an inorganic silicon-based layer formed by chemical vapor deposition (CVD).

6. The method of fabricating a dual damascene structure on a semiconductor substrate as claimed in claim 5, wherein the inorganic silicon-based layer is black diamond, or Coral manufactured by Applied Materials Corporation.

7. The method of fabricating a dual damascene structure on a semiconductor substrate as claimed in claim 1, further comprising the steps of:
electroplating a copper layer to fill the dual damascene structure; and
planarizing the copper layer to form a copper interconnect by chemical mechanical polishing.

8. The method of fabricating a dual damascene structure on a semiconductor substrate as claimed in claim 1, further comprising the step of forming a sealing layer to cover the conductive structure.

9. The method of fabricating a dual damascene structure on a semiconductor substrate as claimed in claim 8, wherein the sealing layer is silicon oxy-nitride or silicon nitride.

10. The method of fabricating a dual damascene structure on a semiconductor substrate as claimed in claim 1, further comprising the step of forming an anti-reflection coating layer overlaying the deposited dielectric layer.

11. The method of fabricating a dual damascene structure on a semiconductor substrate as claimed in claim 10, wherein the anti-reflection coating layer is titanium/titanium nitride formed by chemical vapor deposition.

12. The method of fabricating a dual damascene structure on a semiconductor substrate as claimed in claim 10, wherein the anti-reflection coating layer is silicon oxy-nitride formed by chemical vapor deposition.

13. A method of fabricating a dual damascene structure on a semiconductor substrate having a conductive structure, comprising the steps of:
sequentially forming a first dielectric layer, a second dielectric layer, and a hard mask with a via opening on the semiconductor substrate;
forming a photoresist pattern having a trench opening on the hard mask, wherein the photoresist pattern has the same etching characteristic as the second dielectric layer;
etching the second dielectric layer through the via opening while the hard mask is used as the etching mask;
etching the hard mask using the photoresist pattern as the etching mask to create a damascene opening including the via opening and the trench opening;
etching the second dielectric layer and the first dielectric layer through the damascene opening to form a dual damascene structure; and
forming a copper layer to fill the dual damascene structure to form a copper interconnect.

14. The method of fabricating a dual damascene structure on a semiconductor substrate as claimed in claim 13, wherein the second dielectric layer is spin-on polymer (SOP) formed by spin-coating.

15. The method of fabricating a dual damascene structure on a semiconductor substrate as claimed in claim 14, wherein the spin-on polymer is SilK manufactured by Dow Chemical Corp, fluorinated poly (arylene ether) (FLARE) manufactured by Applied Signal Corporation, poly (arylene ether), or fluorine-doped silicon glass.

16. The method of fabricating a dual damascene structure on a semiconductor substrate as claimed in claim 13, wherein the first dielectric layer is a silicon-based layer formed by chemical vapor deposition (CVD).

17. The method of fabricating a dual damascene structure on a semiconductor substrate as claimed in claim 16, wherein the first dielectric layer is black diamond, or Coral manufactured by Applied Materials Corporation.

18. The method of fabricating a dual damascene structure on a semiconductor substrate as claimed in claim 13, wherein the formation of the hard mask with a via opening further comprises the steps of:
depositing a silicon nitride layer on the second dielectric layer;
forming a photoresist pattern with a via opening on the silicon nitride layer;
etching the silicon nitride layer through the via opening to create a hard mask; and
removing the photoresist pattern.
